(19) United States
(12) Patent Application Publication
(10) Pub. No.: US 2016/0377658 A1
(43) Pub. Date: Dec. 29, 2016

(54) FLUID FLOW IN A TEMPERATURE CONTROL ACTUATOR FOR SEMICONDUCTOR DEVICE TEST

(71) Applicant: INTEL CORPORATION, Santa Clara, CA (US)

(72) Inventors: Paul J. DIGLIO, Chandler, AZ (US); John C. JOHNSON, Phoenix, AZ (US); Weihua TANG, Chandler, AZ (US)

(73) Assignee: INTEL CORPORATION, Santa Clara, CA (US)

(21) Appl. No.: 14/748,976

(22) Filed: Jun. 24, 2015

(51) Int. Cl. G01R 1/44; G01R 31/26

(52) U.S. Cl. CPC G01R 1/44; G01R 31/2601

(57) ABSTRACT

Improved fluid flow is described for a temperature control actuator that is used in semiconductor device test. In one example, the apparatus includes a top plate configured to thermally connect to a semiconductor device under test, a channel plate thermally connected to the top plate and having a plurality of fluid channels to receive a thermally controlled fluid from an inlet to exchange heat with the thermally controlled fluid in the channel and to eliminate the thermally controlled fluid to an outlet, a manifold to provide the thermally controlled fluid to the inlet and to receive the thermally controlled fluid through the outlet, and a flow guide in the channel thermally connected to the top plate.

### FIELD

The present disclosure relates to fluid channel flow in a temperature control actuator used during semiconductor device test.

### BACKGROUND

Semiconductor devices are subjected to a variety of tests after manufacture and before shipping. Tests may be conducted before the devices are packaged or after the devices are packaged. In some tests a sequence of commands are fed to the input and output electrical connections of the device to determine whether the device produces a correct output for each input. The commands may use normal data connections or special test contacts. In these tests, the temperature of the device is monitored and maintained. Some tests are run at a typical operation temperature while other tests are run at low or high temperatures to determine whether the device functions properly under a variety of thermal conditions.

The temperature of each device in a test is controlled and may also be monitored using a temperature control actuator. One actuator is typically applied to each device singularly and is in contact with a defined thermal interface surface on the device. There is a variety of electrical and thermal contact configurations but typically, the electrical contacts are on the front side of the device and heat transfer for thermal control is accomplished on the back side of the device or package.

The temperature control actuator applies or removes heat from the device via conduction contact between the device and the temperature controlled surface of the actuator. A typical temperature control actuator is implemented using a fluidic channel thermal control mechanism which removes heat generated by device during test. Optionally, device heating can be provided by an element thermo-mechanically coupled to the fluidic channels. A cooling fluid (liquid or gas) flows through the channels to remove device heat which is then sent to a remote heat exchanger.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is side cross-sectional view diagram of a portion of a semiconductor device temperature control actuator according to an embodiment.

FIG. 2 is a transverse cross-sectional view diagram of a fluid flow channel according to an embodiment.

FIG. 3 is a transverse cross-sectional view diagram of an alternative fluid flow channel according to an embodiment.

FIG. 4 is a longitudinal cross-sectional view diagram of the fluid flow channel of FIG. 2 taken through line 4-4.

FIG. 5 is a transverse cross-sectional view diagram of an alternative fluid flow channel according to an embodiment.

FIG. 6 is a transverse cross-sectional view diagram of an alternative fluid flow channel according to an embodiment.

FIG. 7 is a transverse cross-sectional view diagram of an alternative fluid flow channel according to an embodiment.

FIG. 8 is a longitudinal cross-sectional view diagram of another fluid flow channel.

### DETAILED DESCRIPTION

Many semiconductor device temperature control actuators use a cooling (or heating) micro-channel heat exchange technology. The micro channel is an enclosed fluid path with a dimensionally small cross section and high surface to volume ratio to ensure good fluid flow velocity against the channel's wall surfaces for enhanced heat transfer. In some micro-channel designs the fluid inlet and outlet ports are arranged so that the fluid enters and exits normal to the direction of fluid flow within the channel. This type of micro-channel architecture allows for multiple entry and exit ports within a single channel resulting in a shorter path for the fluid within the channel. Reducing the path length within the micro channel improves heat transfer. The shorter fluid path is less likely to be thermally saturated. This structure is sometimes referred to as a short loop microchannel (SLMC).

The heat transfer efficiency within the SLMC is affected by fluid properties and thermal conductivity of the material used to construct the SLMC. The heat transfer efficiency is also affected by the surface area and geometry of the fluid/wall interface and the surface level velocity of fluid across the wall.

Heat transfer efficiency may therefore be increased by reducing the passage size, reducing the pitch of inlet/outlets ports and increasing the mass flow rate of the heat transfer fluid. These approaches may all be limited by manufacturing capabilities, materials, insulation requirements, pumping energy, and other limitations on the overall system. Some changes may be impractical and others may be impossible.

Heat transfer efficiency may also be improved, as described herein, using a flow guide in the fluid micro channel. The guide may be thermally coupled to the channel surfaces so that the guide's surfaces provide additional heat transfer area within the fluid channel. The flow guide as described herein may serve two or more roles. First, it is a space filler that provides a higher fluid surface velocity through the channel at lower fluid mass flow rates. Second, it provides a surface area to exchange heat between the fluid and the heat load conduction path in the same way that the micro channel walls do. By fabricating the micro channel wall and device contact surface from the same part as the flow guide and from a thermally conductive material, a robust heat flow path is formed to the thermal conduction surface of the semiconductor device.

The effective heat transfer surface area within a micro channel can be nearly doubled by adding a flow guide into the channel. This may be done without decreasing the channel pitch or spacing within a fluid manifold. The improvement in heat transfer rate may be more than double due to the effects of the fluid temperature differential.

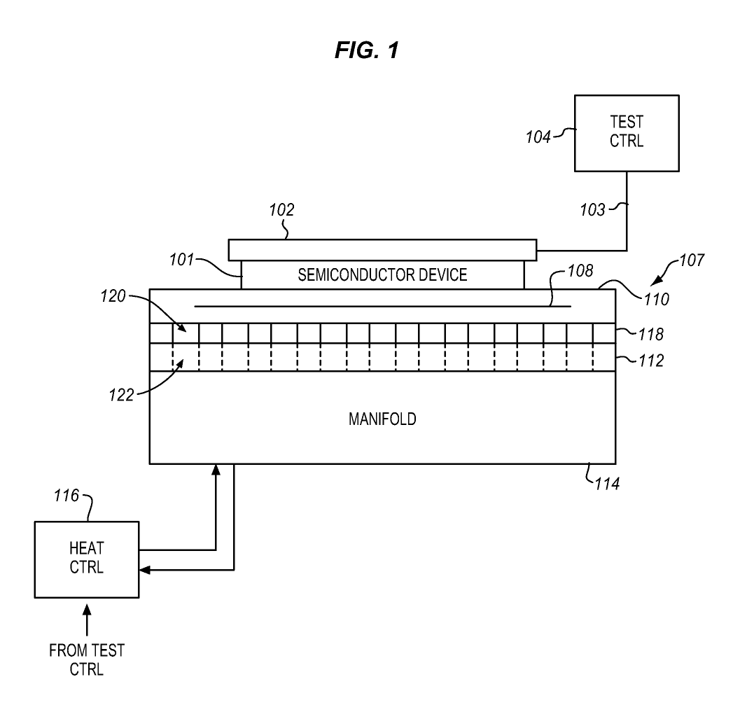

FIG. 1 is a cross-sectional diagram of a semiconductor device 101 attached to a thermal control system 107 for a test system. The device is mounted to a socket 102 or other connector to send and receive test signals and power. The signals and power are coupled through a cable 103 to a test controller 104. There may be circuit boards, cables, and many other components in addition to the one cable 103 between the socket or other connector 102 and the test controller 104. The test controller may be coupled to many different semiconductor devices simultaneously.

The temperature control actuator 107 has a top plate 110 with an optional integral heat generating element 108. The top plate 110 is thermo-mechanically coupled to a channel plate 118, a grooved structure that has a series of fluid channels 120. The grooved structure is thermally conductive to promote the transfer of heat from the semiconductor device to the top plate to the channel plate and then to the channels 120.

A heat controller 116 pumps fluid through a manifold 114. The fluid is thermally controlled by the heat controller and may be heated or cooled, depending on the type of test and the implementation. The manifold directs the fluid into and out of each of the fluid channels 120. The fluid absorbs heat from the channel plate and the fluid returns to the heat controller. The heat controller may include a pump, a heat exchanger, and other components including a thermal control system. For cooling, the fluid is returned to the heat exchanger from the manifold, is cooled, and then pumped back into the manifold. From the manifold, the fluid enters the fluid channels to absorb heat and be pumped back through the manifold to the heat exchanger. Alternately for heating, the heat exchanger can heat the fluid. The fluid carries this heat to the channel plate where the heat is absorbed and the cooler fluid returns to the heat exchanger to be heated. A thermal control system may be used to heat or cool the fluid so that the semiconductor device temperature is controlled.

The manifold 114 has a series of passages to distribute incoming and outgoing fluid into the channel plate. These passages are coupled to an isolation plate 112 between the manifold and the channel plate. The isolation plate has inlet and outlet holes 122 to feed the fluid between the manifold and the channels. The isolation plate serves to thermally insulate the manifold and the channel plate from each other. The channel plate is at or near the desired temperature of the semiconductor device. The manifold carries both inlet fluid and outlet fluid which is both cool and hot. The isolation plate serves to prevent the transfer of heat in either direction between the cool or hot fluid of the manifold and the cooling channels. This is so that the heat transfer is primarily with the fluid in the channels of the channel plate.

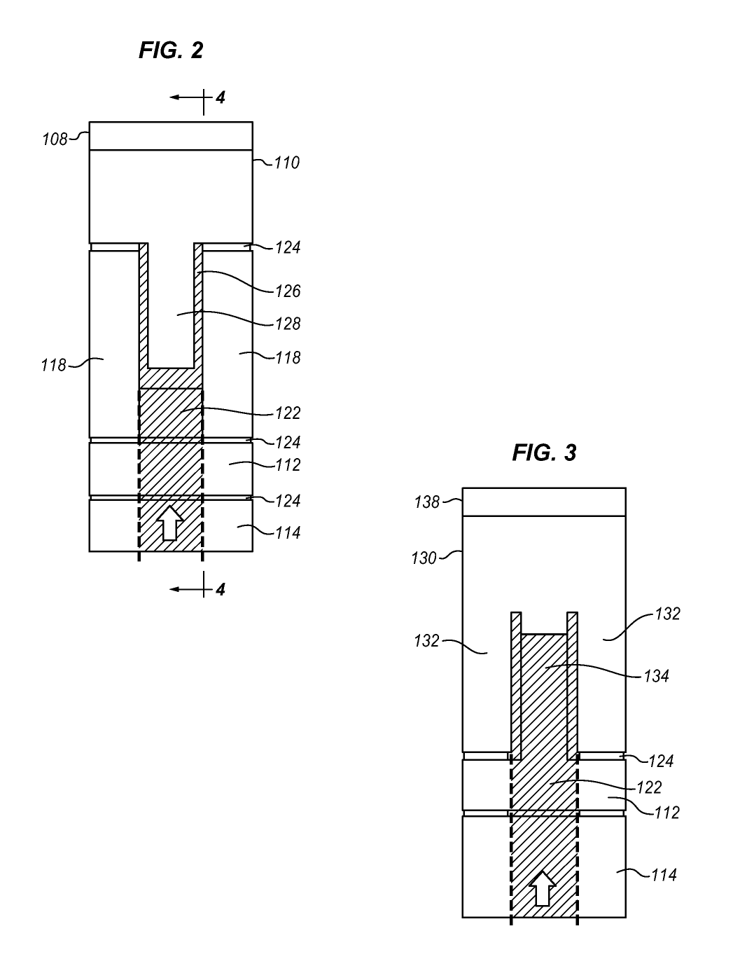

FIG. 2 is a transverse cross-sectional view of a single fluid flow channel of a temperature control actuator showing many of the same components as in FIG. 1. The top plate 110 is configured to connect directly to the device under test (DUT), a semiconductor device in FIG. 1. The top plate optionally includes a heater element 108 and attaches to a channel plate 118. The top plate and channel plate are coupled together with a bonding agent 124 or adhesive. The bonding agent may be made thermally conductive or it may be made very thin so that heat transfers readily across the bond. In typical operation the DUT generates heat which is transferred to the top plate. The heat from the top plate is transferred to the channel plate and from the channel plate to the fluid in the channels. The fluid is then pumped to the thermal controller to absorb the heat.

The channel plate 118 has channel walls on either side of the channel. As shown, there is a left side wall and a right side wall as well as a bottom wall or floor which in this case is obscured by the inlet port 122. These walls may also be considered as grooves in the channel plate. The grooves are aligned with inlet and outlet ports 122 that conduct fluid from the manifold through the isolation plate to the channel. The channel plate is fastened to the isolation plate 112 with another bonding agent and the isolation plate is attached to the manifold 114 with a bonding agent. This may be the same or a different bonding agent. The bonding agent may be thermally conductive or thermally insulating. The isolation plate is thermally insulating so that even if heat is transferred through the bonding agent, most of the heat transfer is prevented by the isolation plate.

The top plate in this example includes a flow guide 128 that extends down from the top plate into the channel. The flow guide fills most of the volume of the channel and provides a significant additional surface area across which the fluid flows. The flow guide is formed by ribs or tabs extending from the bottom surface of the top plate and consists of the same thermally conductive material. The flow guide similarly has a left side wall proximate the left side wall of the channel and a right side wall proximate the right side wall of the channel. The proximity of these walls determine how large the flow channel is on either side of the fin. The flow guide extends across the transverse volume of the channel as shown and fills most of the transverse volume of the channel.

FIG. 3 is a second transverse cross-sectional view diagram of a fluid channel that shows an alternative configuration in which the flow guide 134 and the channel walls are both formed from the top plate 130. In contrast to the previous embodiment in which the top plate and the channel plate are fastened together with an adhesive, in this embodiment, the top plate and the channel plate are a single integral component. The top plate still has an optional heating element 138 but is connected directly to the isolation plate 112 with a bonding agent 124. As in the other example, the isolation plate provides inlet and outlet ports 122 between the manifold and the channel. In this example there is no separate channel plate because the channel grooves, the flow guide and the top plate are all formed from one piece. This single piece construction provides better heat flow between the channel walls and the top plate, however, it may be more difficult to manufacture.

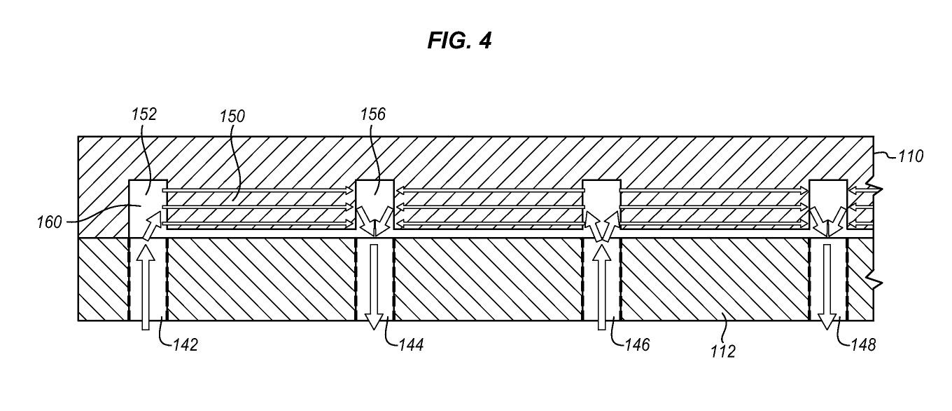

FIG. 4 is a longitudinal cross-sectional view diagram of a fluid channel taken through line 4-4 of FIG. 2. It is clearly seen here that the fluid channel is elongated from left to right. The flow guide 150 extends longitudinally through the channel and films most of the length of the channel. In this diagram the side of the flow guide within the fluid channel may be seen as the fluid passes across the flow guide. One wall of the chamber is removed for this cross-section and the other wall is obscured by the flow guide. Fluid enters the channel 152 through inlet ports 142, 146. The back wall of the chamber 160 may be seen on either side of the flow guide near the inlet and outlet ports. The fluid is pumped in under pressure from the heat exchanger.

The fluid flows through the channel to the exit ports 144, 148. The left inlet port 142 represents the left end of the top plate or channel plate so that the fluid flows only to the right to exit at the next port 144 which is an outlet port. The fluid is heated or cooled as it flows across the flow guide and across the channel wall to the outlet port 144. It then exits through the outlet port, returns to the heat exchanger, is restored to the intended temperature, and then returned back to the inlet ports.

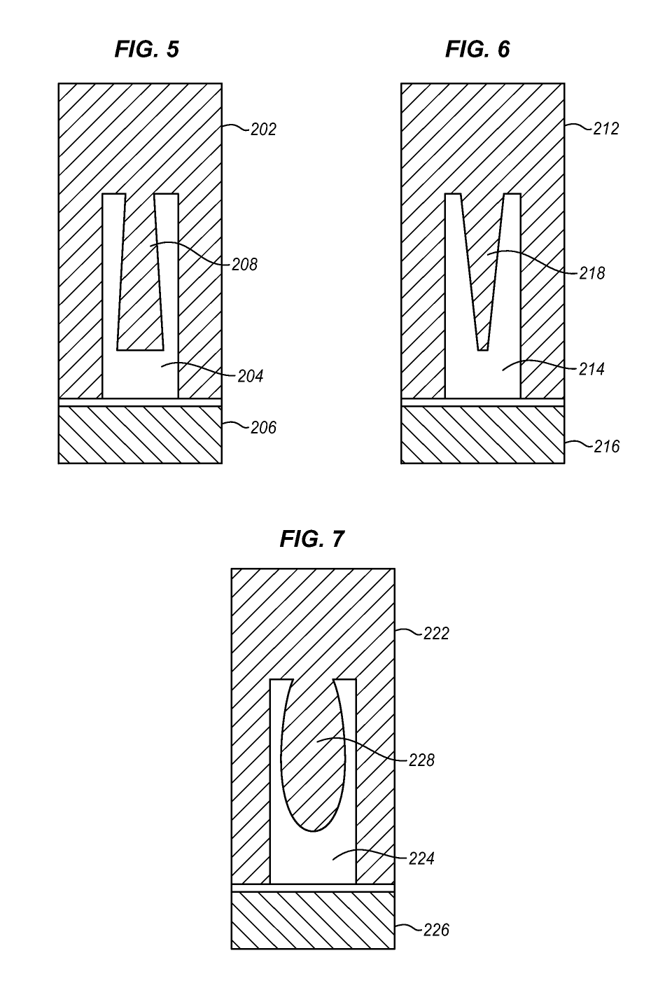

The third port 146 from the left is another inlet port and fluid travels as shown by arrows into the fluid channel and is pushed in both directions away from the inlet port. This drives the fluid toward the two adjacent outlet ports one on the left 144 and the other on the right 148. The two outlet ports both receive fluid from both directions, the left and the right as shown in the diagram. The other inlet and outlet port operate in this bi-directional manner except for the inlet ports at either end of the channel. As shown in FIG. 5, the flow guide presents a heat conduction surface to the fluid as it travels through the channel. The particular flow patterns and port configuration is shown as an example only. The fluid flow for each channel may be modified, combined, or isolated, depending on the particular implementation.

FIG. 5 is a transverse cross-sectional view of the fluid channel similar to that of FIG. 2 that shows an alternative configuration for the flow guide in the channel. A combined top and channel plate 202 is shown fastened to an isolation plate 206. The top plate 202 has a groove to form a channel 204 with a flow guide 208 within portions of the channel as shown in FIG. 4. The top plate 202 may be formed from two pieces as shown in FIG. 2 or more than two pieces, depending on the particular implementation. The flow guide extends into the channel from the top as a trapezoidal cross-sectional extension or rib. The flow guide is narrow at the top and wider at the bottom. The flow guide as shown has a left side wall proximate the left side wall of the channel and a right side wall proximate the right side wall of the channel. In contrast to the example of FIG. 2, the left and right side walls of the flow guide are not parallel to the left and right side walls of the channel. The flow guide wall diverge with distance from the top plate.

In this case, the top refers to the top as shown in the diagram. This is the side of the temperature control actuator that is closest to the device under test. In use the temperature control actuator may be inverted so that the thermal conduction surface of the device is directed upwards and the electrical contacts of the device are directed downwards. The top plate is then placed over the device so that the manifold is over the top plate. In practice, any orientation of the temperature control actuator is possible, even those where the device's thermal conduction surface is shared with its electrical connections. In that case, the temperature control actuator top plate is integrated with the electrical contact mechanism.

FIG. 6 shows a similarly combined top plate and channel plate 212 fastened to an isolation plate 216 to form a channel 214. The top plate has a flow guide 218 with a triangular cross-section that extends into the channel with a wider base at the top and a narrowed end. In this example, the narrowed end comes to a point near the bottom of the channel but this end may be rounded or squared off. In other words, the left and right side walls of the flow guide converge with distance from the top plate. This may allow for a higher flow rate but with less heat exchange.

The angled sides of the flow guides in FIGS. 5 and 6 serve to alter the flow through the channel. In the example of FIG. 5, the flow is constrained at the bottom and will tend to be driven to the top of the channel by the larger available area. This may reduce the flow rate but it will increase thermal exchange with the top plate at the top surface of the channel. On the other hand the flow guide of FIG. 6 will tend to increase the flow rate and reduce the amount of fluid at the top of the channel. The version in FIG. 6 will require less pump pressure to obtain the same fluid flow rate and rely more on thermal conduction from the top plate into the flow guide.

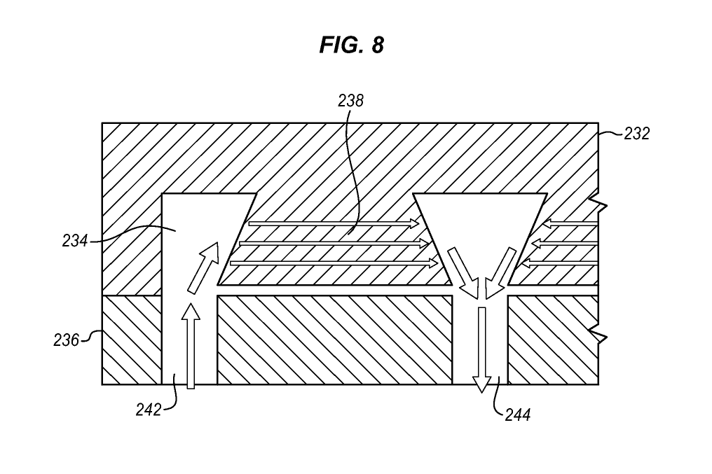

FIG. 7 shows an alternative combined top plate and channel plate 222 that forms a channel 224 when fastened over an isolation plate 226. The channel includes a flow guide 228 with curved surfaces. The curved surfaces combine features of FIGS. 5 and 6. The curved flow guide 228 is narrow at the top where it attaches to the top plate. The narrow section provides a larger fluid volume at the top of the channel. The flow guide is then wider at the middle of the channel before narrowing to a point near the bottom of the channel to increase the flow rate. While this flow guide is shown with curved sides, a similar shape may be formed with straight sides and angles. Similarly the flow guides of FIGS. 5 and 6 may be formed with curved sides.

A smooth, curved cross section rather than a rigid rectangular structure may reduce fluid resistance. Rectangular structures or sudden changes in flow direction can create swirls, eddy currents and similar phenomena.

The flow guide may be designed to balance a desirable high flow rate, a desired surface contact area with the top plate and the flow guide, and a desired fluid pump pressure. Different flow guide shapes may be used, depending on the cooling or heating demands for the system and the ease or difficulty of fabricating different flow guide shapes. The flow guide may fill different amounts of the transverse volume of the channel. As for example in FIG. 5, the flow guide fills more of the channel than in FIG. 6. FIG. 5, accordingly provides more flow restriction requiring more pump pressure but also forces a larger portion of the fluid to contact the walls of the flow guide and the channel. In each case, more than half of the transverse volume of the channel is filled. Each of the pieces may be made as one or more different sections to be combined together through brazing, soldering, welding, adhesives or some combination.

FIG. 8 is a longitudinal cross-sectional side view diagram of a fluid channel similar to that of FIG. 4. A combined top plate and channel plate 232 is attached to an isolation plate 236 to form a fluid channel 234. A flow guide 238 extends into the channel similar to FIG. 4. Fluid flows from an inlet port 242 to an outlet port 244. In contrast to the rectangular and vertical sides of the flow guide in FIG. 4. The flow guide has a left side that angles to the right at the port on its left side as it extends toward the top plate and the angles to the left on the at the port on the right side as it extends toward the top plate.

As a result, the channel is larger than the inlet port and increases in size with vertical distance from the inlet port. At the inlet port and the outlet port, the channel over the port has a larger volume at the top than at the bottom. This reduces the pressure in the channel and draws fluid from the inlet port. As it moves into the larger volume it is then pushed aside by the flow guide through the narrower sides of the channel across the flow guide. At the outlet side the volume of the channel increases again as the fluid passes the flow guide and expands into the larger volume. This increases the flow rate across the fin. The channel then narrows to the outlet port due to the diagonal sides of the flow guide. This guides the fluid into the outlet port while increasing the fluid pressure. As shown, the flow of the fluid may be adjusted by modifying the shape of the flow guide within the channel.

In the configuration of FIG. 8 and in the other configurations described herein, the flow guide serves to reduce eddy currents, boundary layers, laminar flow and other phenomena that affect the efficiency of heat transfer between the channel and the fluid. The angled flow guides reduce abrupt direction changes for a smoother flow through the channel.

The flow guide also serves to reduce the size or interior volume of the channel. In a larger channel, the most rapid portions of the fluid will flow through the middle of the channel out of contact with the surface of the channel plate. The smaller or narrower channel forces the mainstream fluid flow closer to the surface of the channel plate. The fluid resistance of the channel is increased because the cross sectional surface area through which the fluid flows has been decreased. Thus, for the same fluid velocity, the former approach has reduced efficiency because not enough of the rapidly flowing fluid is in contact with the surface of the channel plate. The latter approach has reduced efficiency because it requires a more powerful pump. These factors are balanced and both are improved by the flow guides.

The flow guide provides significant thermal and mechanical benefits. The channel-plate may be a separate physical component from the top plate with its active surface in contact with the device under test. The channel plate may be manufactured out of a variety of different thermally conductive materials, such as Aluminum Nitride, Tungsten, etc., that provide additional thermal coupling to the surface of the device under test. When the channel plate is separate from the top plate structure it may be made from similar or identical thermally expansive materials. This reduces or eliminates mechanical stresses between the part junctions during thermal cycling and fluid flow.

The materials of the channel and test head components, such as the heater and channel plate, may be selected to have a high thermal conductivity and a CTE (Coefficient of Thermal Expansion) that is similar to the manifold and intermediate components. This reduces the mechanical stress that may be caused from any CTE mismatch. The described isolation plate is placed between the SLMC and manifold to reduce the heat transfer with the manifold.

The thermally conductive flow guide within the fluid flow channel adds an additional thermally conductive surface area for fluid heat exchange without otherwise affecting the overall thermal test head and manifold structure. The flow guide is able to confine the cross section of the fluid channel. This creates a higher surface velocity without increasing the fluid mass flow rate. The amount of surface area exposed to the fluid may be modified to improve the heat energy exchange.

The cooling channels are used in the system of FIG. 1 in which one or more devices to be tested are electrically connected to a test controller and then the top plate of a thermal control test head is placed over each device. Typically there is one thermal head for each device. A thermal grease or other interface material may be used to improve thermal conductivity between the thermal head and the device.

The test controller operates a test of the device according to a prearranged protocol and sends electrical input signals to the device. The device generates results which are returned to the test controller and recorded. These are used to determine the quality of the device. The device may be operated at different temperatures as may be desired for the test. The test controller may vary the power supply voltage, the clock rate, the work load, and the temperature of the device to support a variety of different tests.

The test controller can ramp the temperature of each device up or down as desired for the particular test. The heat exchanger may provide a single fluid supply to each device so that each device may operate at different temperatures while the amount of cooling is the same. With enough thermal efficiency and thermal fluid, all of the devices may be kept at the same temperature regardless of the amount of heat produced by each device. If the test program requires cold testing conditions, then the cooling fluid will extract extra heat out of the silicon device through the top plate. On the other hand if warm conditions are required, then the fluid may be heated to bring each device up to the same temperature. During the test process, fluid will flow through the thermal fluid channels at varying rates depending on the temperature setpoint of the device. The flow rate and the temperature of the fluid may be controlled by the heat controller.

After the test controller has completed the tests, then the thermal head is removed from the device. The device is electrically disconnected, for example by unsocketing the device. The device is removed and then the next device is installed to be tested.

Embodiments may be implemented with parts including one or more memory chips, controllers, CPUs (Central Processing Unit), microchips or integrated circuits interconnected using a motherboard, an application specific integrated circuit (ASIC), and/or a field programmable gate array (FPGA).

References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified, the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

The following examples pertain to further embodiments. The various features of the different embodiments may be variously combined with some features included and others excluded to suit a variety of different applications. Some embodiments pertain to an apparatus that includes a top plate configured to thermally connect to a semiconductor device under test, a channel plate thermally connected to the top plate and having a plurality of fluid channels to receive a thermally controlled fluid from an inlet to exchange heat with the thermally controlled fluid in the channel and to eliminate the thermally controlled fluid to an outlet, a manifold to provide the thermally controlled fluid to the inlet and to receive the thermally controlled fluid through the outlet, and a flow guide in the channel thermally connected to the top plate.

In further embodiments the flow guide is between the inlet and the outlet.

In further embodiments the flow guide has a left side wall proximate a left side wall of the channel and a right side wall proximate a right side wall of the channel and wherein the left and right side walls of the flow guide are not parallel to the left and right side walls of the channel.

In further embodiments the left and right side walls of the flow guide diverge with distance from the top plate.

In further embodiments the channel is elongated and has a transverse volume and wherein the flow guide fills more than half of the transverse volume.

In further embodiments the channel is elongate and the flow guide extends longitudinally through the channel.

In further embodiments the top plate and the channel plate are a single integral component.

In further embodiments the top plate and the channel plate are fastened together with an adhesive.

In further embodiments the flow guide and the top plate are a single integral component.

In further embodiments the top plate forms a top wall of the channel and the flow guide extends from the top plate into the channel.

Further embodiments include an isolation plate between the manifold and the channel plate to thermally insulate manifold and the channel plate.

In further embodiments the channel plate forms a plurality of short loop micro-channels.

Some embodiments pertain to a semiconductor device test system that includes a test controller to drive a test of a semiconductor device under test (DUT), a connector coupled to the test controller and to the DUT to send and receive electrical signal to and from the DUT, a heat controller coupled to the test controller and the DUT to cool a thermal fluid, and a temperature control actuator coupled to the heat controller to receive the thermal fluid, the temperature control actuator having a top plate configured to thermally connect to a semiconductor device under test, a channel plate thermally connected to the top plate and having a plurality of fluid channels to receive the thermally controlled fluid from an inlet to exchange heat with the thermally controlled fluid in the channel and to eliminate the thermally controlled fluid to an outlet, a manifold to provide the thermally controlled fluid to the inlet and to receive the thermally controlled fluid through the outlet, and a flow guide in the channel thermally connected to the top plate.

In further embodiments the channel is elongated and has a transverse volume and wherein the flow guide fills more than half of the transverse volume.

In further embodiments the top plate and the channel plate are a single integral component.

Some embodiments pertain to a method that includes applying a cooled fluid from a thermal controller to a manifold of a temperature control actuator of a semiconductor device test system, driving the cooled fluid through the manifold to a fluid channel that is formed between a top plate and a channel plate thermally connected to the top plate, the top plate being configured to thermally connect to a semiconductor device under test, driving the cooled fluid through the fluid channel and between side walls of the channel and side walls of a flow guide in the channel, the flow guide being thermally connected to the top plate, and receiving the cooled fluid from the channel at a thermal controller through the manifold.

In further embodiments the channel has an inlet and an outlet and the flow guide is between the inlet and the outlet.

In further embodiments the channel is elongate and the flow guide extends longitudinally through the channel.

In further embodiments the flow guide and the top plate are a single integral component.

Further embodiments include driving the device under test in an active mode in which the device under test produces heat, wherein the top plate absorbs heat from the device under test and conducts the absorbed heat to the cooled fluid.

What is claimed is:

1. An apparatus comprising:
a top plate configured to thermally connect to a semiconductor device under test;
a channel plate thermally connected to the top plate and having a plurality of fluid channels to receive a thermally controlled fluid from an inlet to exchange heat with the thermally controlled fluid in the channel and to eliminate the thermally controlled fluid to an outlet;
a manifold to provide the thermally controlled fluid to the inlet and to receive the thermally controlled fluid through the outlet; and
a flow guide in the channel thermally connected to the top plate.

2. The apparatus of claim 1, wherein the flow guide is between the inlet and the outlet.

3. The apparatus of claim 1, wherein the flow guide has a left side wall proximate a left side wall of the channel and a right side wall proximate a right side wall of the channel and wherein the left and right side walls of the flow guide are not parallel to the left and right side walls of the channel.

4. The apparatus of claim 3, wherein the left and right side walls of the flow guide diverge with distance from the top plate.

5. The apparatus of claim 1, wherein the channel is elongated and has a transverse volume and wherein the flow guide fills more than half of the transverse volume.

6. The apparatus of claim 1, wherein the channel is elongate and the flow guide extends longitudinally through the channel.

7. The apparatus of claim 1, wherein the top plate and the channel plate are a single integral component.

8. The apparatus of claim 1, wherein the top plate and the channel plate are fastened together with an adhesive.

9. The apparatus of claim 1, wherein the flow guide and the top plate are a single integral component.

10. The apparatus of claim 9, wherein the top plate forms a top wall of the channel and the flow guide extends from the top plate into the channel.

11. The apparatus of claim 1, further comprising an isolation plate between the manifold and the channel plate to thermally insulate manifold and the channel plate.

12. The apparatus of claim 1, wherein the channel plate forms a plurality of short loop micro-channels.

13. A semiconductor device test system comprising:
a test controller to drive a test of a semiconductor device under test (DUT);
a connector coupled to the test controller and to the DUT to send and receive electrical signal to and from the DUT;
a heat controller coupled to the test controller and the DUT to cool a thermal fluid; and
a temperature control actuator coupled to the heat controller to receive the thermal fluid, the temperature control actuator having a top plate configured to thermally connect to a semiconductor device under test, a channel plate thermally connected to the top plate and having a plurality of fluid channels to receive the thermally controlled fluid from an inlet to exchange heat with the thermally controlled fluid in the channel and to eliminate the thermally controlled fluid to an outlet, a manifold to provide the thermally controlled fluid to the inlet and to receive the thermally controlled fluid through the outlet, and a flow guide in the channel thermally connected to the top plate.

14. The system of claim 13, wherein the channel is elongated and has a transverse volume and wherein the flow guide fills more than half of the transverse volume.

15. The system of claim 13, wherein the top plate and the channel plate are a single integral component.

16. A method comprising:
applying a cooled fluid from a thermal controller to a manifold of a temperature control actuator of a semiconductor device test system;
driving the cooled fluid through the manifold to a fluid channel that is formed between a top plate and a channel plate thermally connected to the top plate, the top plate being configured to thermally connect to a semiconductor device under test;
driving the cooled fluid through the fluid channel and between side walls of the channel and side walls of a flow guide in the channel, the flow guide being thermally connected to the top plate; and
receiving the cooled fluid from the channel at a thermal controller through the manifold.

17. The method of claim 16, wherein the channel has an inlet and an outlet and the flow guide is between the inlet and the outlet.

18. The method of claim 16, wherein the channel is elongate and the flow guide extends longitudinally through the channel.

19. The method of claim 16, wherein the flow guide and the top plate are a single integral component.

20. The method of claim 16, further comprising driving the device under test in an active mode in which the device under test produces heat, wherein the top plate absorbs heat from the device under test and conducts the absorbed heat to the cooled fluid.
